(19) United States
(12) Patent Application Publication
(10) Pub. No.: US 2025/0048782 A1
(43) Pub. Date: Feb. 6, 2025

(54) LIGHT-EMITTING DEVICE AND MANUFACTURING METHOD FOR LIGHT-EMITTING DEVICE

(71) Applicant: Nichia Corporation, Anan-shi (JP)

(72) Inventor: So SAKAMAKI, Anan-shi (JP)

(21) Appl. No.: 18/738,578

(22) Filed: Jun. 10, 2024

(30) Foreign Application Priority Data
Jul. 31, 2023 (JP) 2023-124464

(51) Int. Cl. H01L 33/00; H01L 33/46; H01L 33/62

(52) U.S. Cl. CPC H01L 33/005; H01L 33/46; H01L 33/62; H01L 2933/0025

(57) ABSTRACT

A manufacturing method for a light-emitting device includes: forming a first metal film electrically connecting a first terminal and a first pad on a substrate such that the first metal film covers a part of an upper surface of each of the first terminal and the first pad; forming a first insulating film by insulating a front surface side of the first metal film while maintaining electrical connection between the first terminal and the first pad; mounting a light-emitting element having a first electrode on the substrate by bringing the first electrode into contact with the upper surface of the first terminal; forming a first plating film on surfaces of the first terminal and the first electrode in a state where the first metal film and the first insulating film remain formed; and removing the first insulating film and the first metal film after the first plating film is formed.

### CROSS-REFERENCE TO RELATED APPLICATIONS

The present application claims priority under 35 U.S.C. § 119 to Japanese Patent Application No. 2023-124464, filed Jul. 31, 2023, the entire contents of which are incorporated herein by reference.

### BACKGROUND

### 1. Technical Field

The present disclosure relates to a light-emitting device and a manufacturing method for the light-emitting device.

### 2. Description of Related Art

As a light-emitting device used for a vehicle lamp, lighting, or the like, there is known a light-emitting device in which a plurality of light-emitting elements are mounted on a mounting substrate and a light-reflective material is provided surrounding each of the light-emitting elements. In such a light-emitting device, the plurality of light-emitting elements mounted on the mounting substrate may include a light-emitting element that does not light up. For example, when the quality of the light-emitting device is determined on the basis of the proportion (lighting rate) of light-emitting elements that light up among the plurality of light-emitting elements, a light-emitting device whose lighting rate is less than a reference value is regarded as defective. In addition, in a manufacturing process of the light-emitting device in which a plurality of light-emitting elements are mounted on a mounting substrate, the plurality of light-emitting elements may be bonded to the mounting substrate by plating, and there is known a mounting substrate that allows the bonding by plating. However, when the light-emitting elements are bonded to the mounting substrate by plating, it is difficult to replace one or more light-emitting elements that do not light up after the bonding (for example, see Japanese Patent Publication No. S52-055391).

### SUMMARY

It is desirable to allow a light-emitting element that does not light up to be replaceable and improve yield. In addition, in a light-emitting device, it is desirable to improve yield by suppressing detachment of a light-reflective material from the light-emitting device after manufacturing and improving reliability.

An object of the present disclosure is to provide a light-emitting device having an excellent yield and a manufacturing method for the light-emitting device.

According to one aspect of the technique of the disclosure, a manufacturing method for a light-emitting device includes: on a mounting substrate having a first terminal, a second terminal, a first pad, and a second pad, forming a first metal film electrically connecting the first terminal and the first pad on the mounting substrate such that the first metal film covers a part of an upper surface of the first terminal and a part of an upper surface of the first pad, and forming a second metal film electrically connecting the second terminal and the second pad on the mounting substrate such that the second metal film covers a part of an upper surface of the second terminal and a part of an upper surface of the second pad; forming a first insulating film by insulating a front surface side of the first metal film while maintaining electrical connection between the first terminal and the first pad, and forming a second insulating film by insulating a front surface side of the second metal film while maintaining electrical connection between the second terminal and the second pad; mounting a light-emitting element having a first electrode and a second electrode on the mounting substrate by bringing the first electrode into contact with the upper surface of the first terminal and bringing the second electrode into contact with the upper surface of the second terminal; forming a first plating film on surfaces of the first terminal and the first electrode in a state in which the first metal film and the first insulating film remain formed, and forming a second plating film on surfaces of the second terminal and the second electrode in a state in which the second metal film and the second insulating film remain formed; and removing the first insulating film, the first metal film, the second insulating film, and the second metal film after the first plating film and the second plating film are formed.

According to one aspect of the technique of the disclosure, a light-emitting device includes a mounting substrate having a first terminal, a second terminal, a first pad, and a second pad; a light-emitting element having a first electrode and a second electrode, the first electrode being in contact with an upper surface of the first terminal, the second electrode being in contact with an upper surface of the second terminal; a first plating film formed on surfaces of the first terminal and the first electrode; a second plating film formed on surfaces of the second terminal and the second electrode; and a light-reflective material formed on the mounting substrate and surrounding the light-emitting element in a plan view. A first recessed portion including a part of the upper surface of the first terminal and being recessed toward the first electrode is formed on a lateral surface of the first plating film. A second recessed portion including a part of the upper surface of the second terminal and being recessed toward the second electrode is formed on a lateral surface of the second plating film. The light-reflective material is disposed in the first recessed portion and the second recessed portion.

The present disclosure can provide a light-emitting device having an excellent yield and a manufacturing method for the light-emitting device.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a flowchart of a manufacturing method for a light-emitting device according to a first embodiment.

FIG. 2 is a cross-sectional diagram to illustrate a process step of the manufacturing method for the light-emitting device according to the first embodiment.

FIG. 3 is a cross-sectional diagram to illustrate another process step of the manufacturing method for the light-emitting device according to the first embodiment.

FIG. 4 is a cross-sectional diagram to illustrate another process step of the manufacturing method for the light-emitting device according to the first embodiment.

FIG. 5 is a cross-sectional diagram to illustrate another process step of the manufacturing method for the light-emitting device according to the first embodiment.

FIG. 6 is a cross-sectional diagram to illustrate another process step of the manufacturing method for the light-emitting device according to the first embodiment.

FIG. 7 is a cross-sectional diagram to illustrate another process step of the manufacturing method for the light-emitting device according to the first embodiment.

FIG. 8 is a cross-sectional diagram to illustrate another process step of the manufacturing method for the light-emitting device according to the first embodiment.

FIG. 9 is a cross-sectional diagram to illustrate another process step of the manufacturing method for the light-emitting device according to the first embodiment.

FIG. 10 is a cross-sectional diagram to illustrate another process step of the manufacturing method for the light-emitting device according to the first embodiment.

FIG. 11 is a top-view diagram to illustrate a process step of the manufacturing method for the light-emitting device according to the first embodiment.

FIG. 12 is a top-view diagram to illustrate another process step of the manufacturing method for the light-emitting device according to the first embodiment.

FIG. 13 is a top-view diagram to illustrate another process step of the manufacturing method for the light-emitting device according to the first embodiment.

FIG. 14 is a top-view diagram to illustrate another process step of the manufacturing method for the light-emitting device according to the first embodiment.

FIG. 15 is a top-view diagram to illustrate another process step of the manufacturing method for the light-emitting device according to the first embodiment.

FIG. 16 is a top-view diagram to illustrate another process step of the manufacturing method for the light-emitting device according to the first embodiment.

FIG. 17 is a cross-sectional diagram to illustrate a process step of a manufacturing method for a light-emitting device according to a second embodiment.

FIG. 18 is a cross-sectional diagram to illustrate another process step of the manufacturing method for the light-emitting device according to the second embodiment.

FIG. 19 is a cross-sectional diagram to illustrate another process step of the manufacturing method for the light-emitting device according to the second embodiment.

FIG. 20 is a cross-sectional diagram to illustrate a process step of a manufacturing method for a light-emitting device according to a modified example of the second embodiment.

FIG. 21 is a cross-sectional diagram to illustrate another process step of the manufacturing method for the light-emitting device according to the modified example of the second embodiment.

FIG. 22 is a top-view diagram illustrating a first example of an arrangement of metal films.

FIG. 23 is a top-view diagram illustrating a second example of the arrangement of the metal films.

### DETAILED DESCRIPTION

### Description of Embodiments

Hereinafter, embodiments for implementing the present disclosure are described with reference to the drawings. The following description is intended to embody technical concepts of the present disclosure, and the present disclosure is not limited to the following unless specifically stated.

In each drawing, members having identical functions may be denoted by the same reference characters. In view of the ease of explanation or understanding of the points, the embodiments may be illustrated separately for convenience, but the partial substitutions or combinations of the configurations illustrated in different embodiments and examples are possible. In the embodiments described later, differences from the embodiment described before will be mainly described, and redundant descriptions of commonalities with the embodiment described before may be omitted. The size, positional relationship, and other features of members illustrated in the drawings may be exaggerated in order to clarify explanation. While an XYZ orthogonal coordinate system is used in the following description, the coordinate system is defined for the purpose of description and does not limit the orientation of the light-emitting device. In addition, when viewed from an arbitrary point, a +Z side may be referred to as upper, an upper side, or above, and a −Z side may be referred to as lower, a lower side, or below.

### First Embodiment

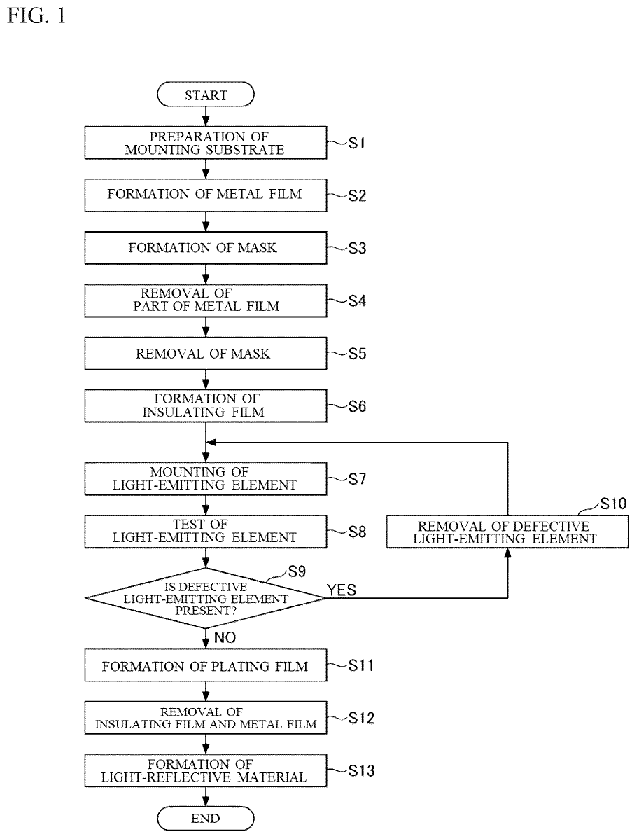

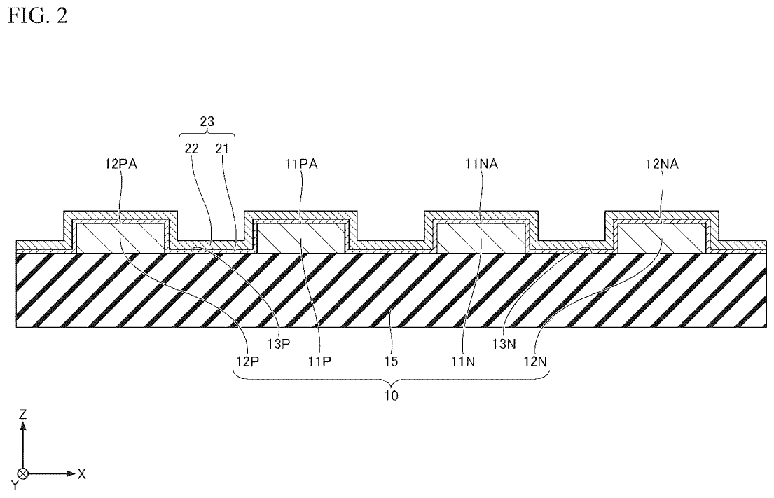

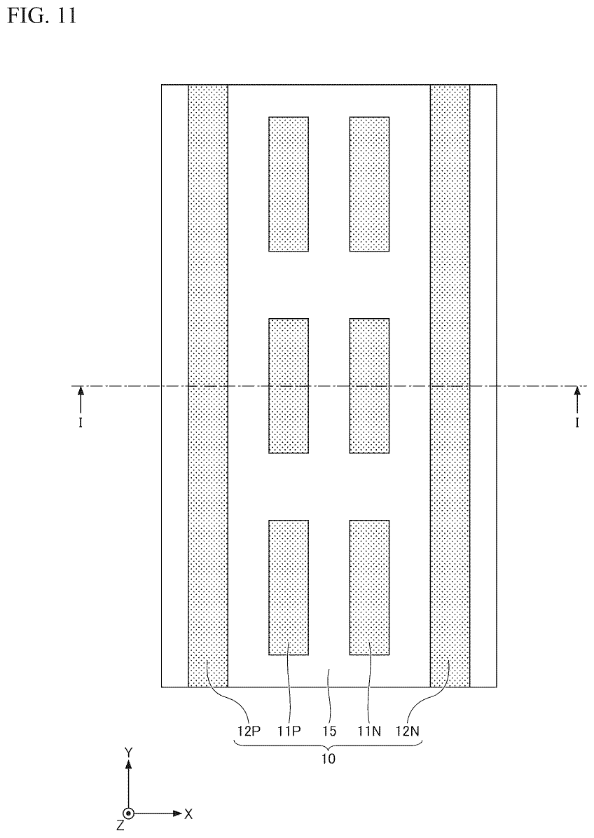

First, a first embodiment will be described. The first embodiment relates to a manufacturing method for a light-emitting device. FIG. 1 is a flowchart of the manufacturing method for the light-emitting device according to the first embodiment. FIGS. 2 to 10 are cross-sectional diagrams to illustrate process steps of the manufacturing method for the light-emitting device according to the first embodiment. FIGS. 11 to 16 are top-view diagrams to illustrate process steps of the manufacturing method for the light-emitting device according to the first embodiment. FIGS. 2 to 10 illustrate cross sections taken along line I-I in FIGS. 11 to 16.

First, as illustrated in FIGS. 2 and 11, a step of preparing a mounting substrate 10 provided with a base material 15, a plurality of P-terminals 11P, a plurality of N-terminals 11N, a P-power supply pad 12P, and an N-power supply pad 12N is performed (Step S1). The base material 15 has two main surfaces parallel to the XY plane, and the P-terminals 11P, the N-terminals 11N, the P-power supply pad 12P, and the N-power supply pad 12N are provided on the main surface on the +Z side. For example, the base material 15 includes a plurality of wiring layers. The P-power supply pad 12P and the N-power supply pad 12N extend along the Y-axis. The plurality of P-terminals 11P are arranged along the Y-axis between the P-power supply pad 12P and the N-power supply pad 12N. The plurality of N-terminals 11N are arranged along the Y-axis between the P-power supply pad 12P and the N-power supply pad 12N. The P-terminal 11P is located between the P-power supply pad 12P and the N-terminal 11N, and the N-terminal 11N is located between the N-power supply pad 12N and the P-terminal 11P. The P-terminal 11P and the N-terminal 11N are adjacent to each other along the X-axis. As materials of the P-terminals 11P, the N-terminals 11N, the P-power supply pad 12P, and the N-power supply pad 12N, materials whose surfaces are hardly oxidized can be used. For example, gold (Au), or a platinum group metal, such as Ru, Rh, Pd, Os, Ir, or Pt can be used. The P-terminal 11P is an example of a first terminal, the N-terminal 11N is an example of a second terminal, the P-power supply pad 12P is an example of a first pad, and the N-power supply pad 12N is an example of a second pad.

Subsequently, as illustrated in FIG. 2, a step of forming a metal film 23 that covers the P-terminal 11P, the N-terminal 11N, the P-power supply pad 12P, the N-power supply pad 12N, a first portion 13P of a front surface of the mounting substrate 10, and a second portion 13N of the front surface of the mounting substrate 10 is performed (Step S2). The first portion 13P is a portion exposed between the P-terminal 11P and the P-power supply pad 12P on the front surface of the mounting substrate 10. The second portion 13N is a portion exposed between the N-terminal 11N and the N-power supply pad 12N on the front surface of the mounting substrate 10. For example, the metal film 23 is formed with a plurality of layers, and one of the layers located closest to the front surface side of the metal film 23 contains aluminum, chromium, or an alloy of tungsten and titanium. In the formation of the metal film 23, for example, a titanium tungsten (TiW) layer 21 is formed, and then an aluminum (Al) layer 22 is formed on the titanium tungsten layer 21. A titanium layer may be formed instead of the titanium tungsten layer 21, and a chromium layer or an alloy layer of tungsten and titanium may be formed instead of the aluminum layer 22. By providing the titanium tungsten layer 21, mutual diffusion between the material of the aluminum layer 22 and the material of each of the P-terminal 11P and the N-terminal 11N can be suppressed. The specific resistance of the metal film 23 is preferably about equal to the specific resistances of the P-terminal 11P and the N-terminal 11N. The metal film 23 is an example of a third metal film.

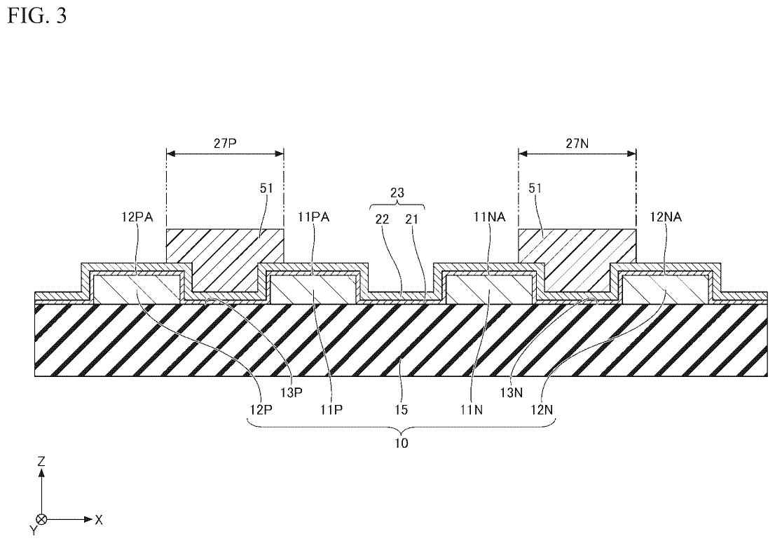

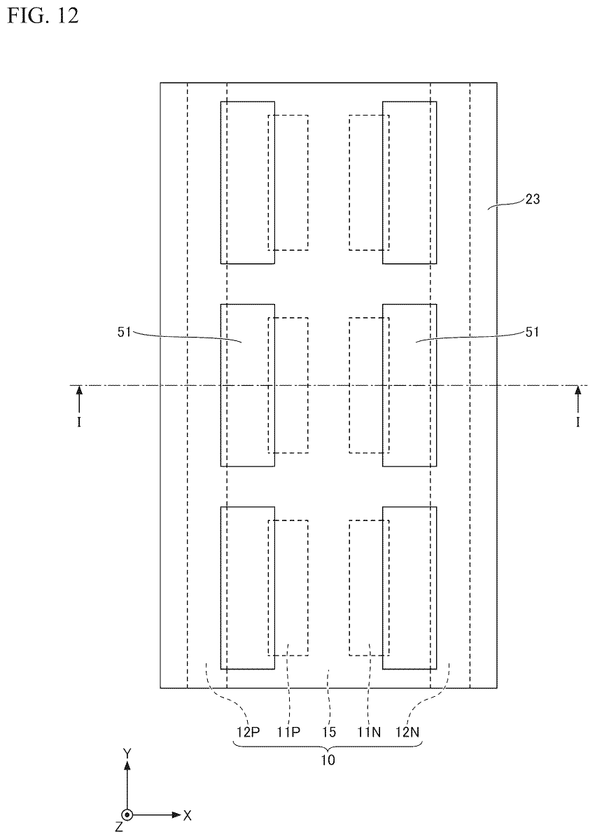

Subsequently, as illustrated in FIGS. 3 and 12, a step of forming a mask 51 on a first region 27P and a second region 27N of the metal film 23 is performed (Step S3). The first region 27P of the metal film 23 is a region that covers the first portion 13P of the mounting substrate 10, a part of an upper surface 11PA of the P-terminal 11P, and a part of an upper surface 12PA of the P-power supply pad 12P. The second region 27N of the metal film 23 is a region that covers the second portion 13N of the mounting substrate 10, a part of an upper surface 11NA of the N-terminal 11N, and a part of an upper surface 12NA of the N-power supply pad 12N. The mask 51 is formed by, for example, applying, exposing, and developing a resist.

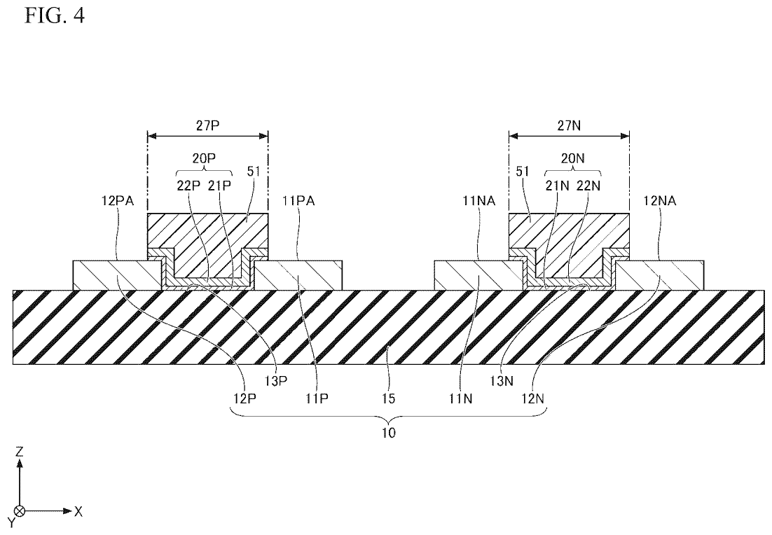

Subsequently, as illustrated in FIG. 4, a step of removing portions of the metal film 23 that are not covered with the mask 51 is performed (Step S4). As a result of this step, in the first region 27P of the metal film 23, a metal film 20P that electrically connects the P-terminal 11P and the P-power supply pad 12P is formed covering a part of the upper surface 11PA of the P-terminal 11P and a part of the upper surface 12PA of the P-power supply pad 12P. In addition, in the second region 27N of the metal film 23, a metal film 20N that electrically connects the N-terminal 11N and the N-power supply pad 12N is formed covering a part of the upper surface 11NA of the N-terminal 11N and a part of the upper surface 12NA of the N-power supply pad 12N. For example, the metal film 20P includes a titanium tungsten layer 21P and an aluminum layer 22P on the titanium tungsten layer 21P, and the metal film 20N includes a titanium tungsten layer 21N and an aluminum layer 22N on the titanium tungsten layer 21N. The first region 27P of the metal film 23 in which the mask 51 is formed in Step S3 is a region to be the metal film 20P, and the second region 27N of the metal film 23 in which the mask 51 is formed in Step S3 is a region to be the metal film 20N. In the step of removing the portions of the metal film 23 that are not covered with the mask 51, dry etching may be performed or wet etching may be performed. The metal film 20P is an example of a first metal film, and the metal film 20N is an example of a second metal film.

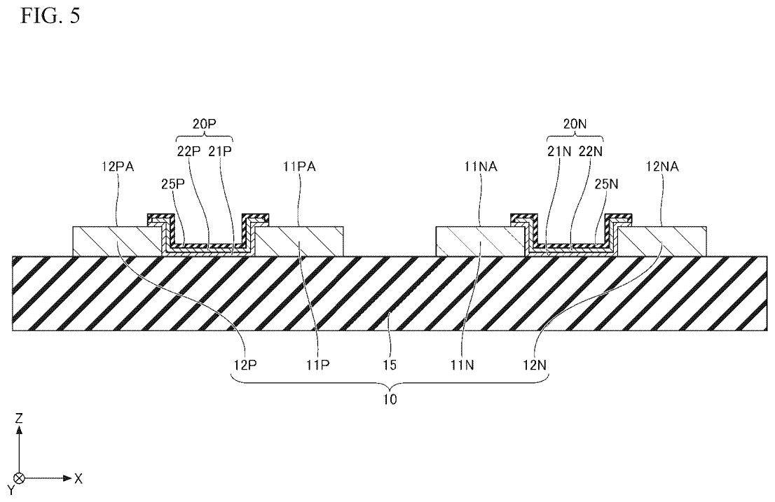

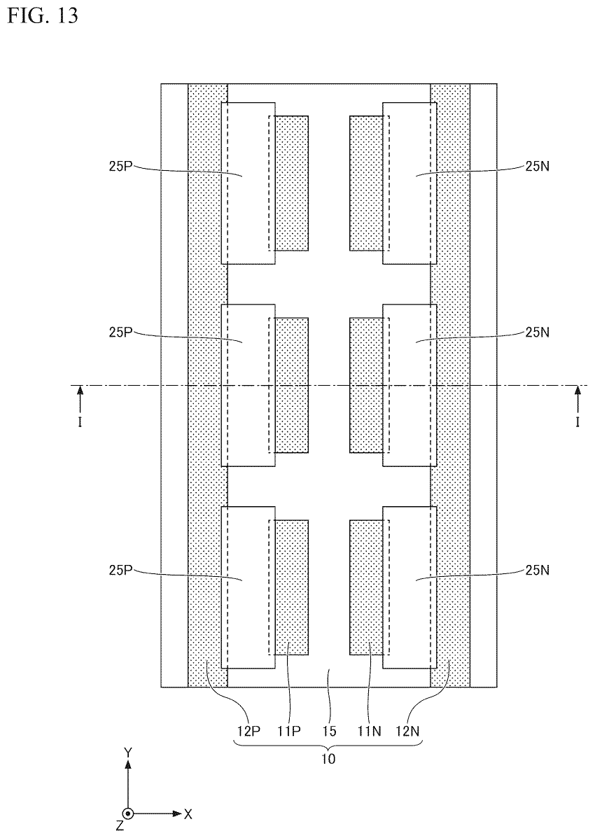

Subsequently, as illustrated in FIGS. 5 and 13, a step of removing the mask 51 is performed (Step S5). Further, a step of forming an insulating film 25P by insulating the front surface side of the metal film 20P while ensuring the electrical connection between the P-terminal 11P and the P-power supply pad 12P, and forming an insulating film 25N by insulating the front surface side of the metal film 20N while ensuring the electrical connection between the N-terminal 11N and the N-power supply pad 12N is performed (Step S6). For example, by performing heat treatment at a temperature of about 200° C. in the atmosphere, an aluminum oxide film is formed, as the insulating film 25P, on a front surface of the aluminum layer 22P, and an aluminum oxide film is formed, as the insulating film 25N, on a front surface of the aluminum layer 22N. At this time, the aluminum layer 22P and the aluminum layer 22N are not entirely oxidized, but a portion for ensuring the electrical connection between the P-terminal 11P and the P-power supply pad 12P remains in the aluminum layer 22P, and a portion for ensuring the electrical connection between the N-terminal 11N and the N-power supply pad 12N remains in the aluminum layer 22N. In the insulation, nitridation may be performed instead of oxidation. The insulating film 25P is an example of a first insulating film, and the insulating film 25N is an example of a second insulating film.

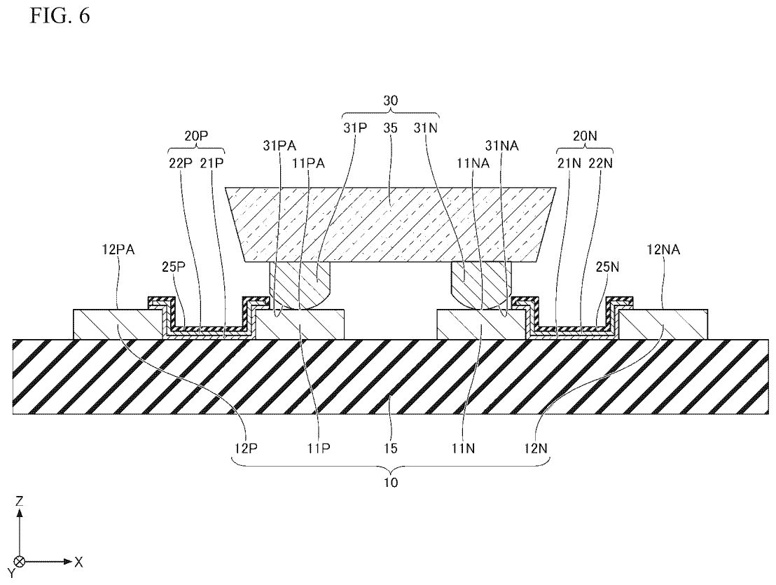

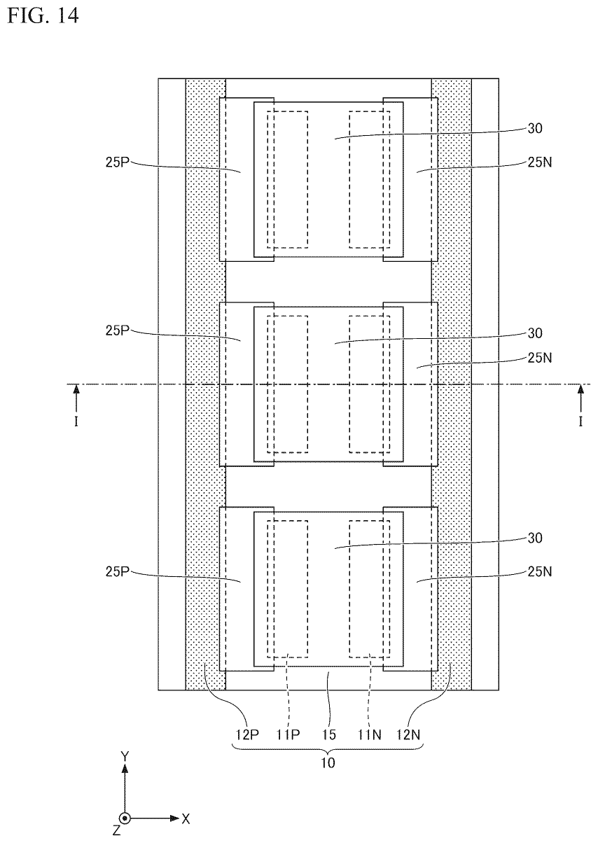

Subsequently, as illustrated in FIGS. 6 and 14, a step of mounting a light-emitting element 30 having a base portion 35, a P-electrode 31P, and an N-electrode 31N on the mounting substrate 10 by bringing the P-electrode 31P into contact with the upper surface 11PA of the P-terminal 11P and bringing the N-electrode 31N into contact with the upper surface 11NA of the N-terminal 11N is performed (Step S7). At this time, a plurality of the light-emitting elements 30 are mounted on the mounting substrate 10. For example, 10000 or more light-emitting elements 30 are thermally compression-bonded to the mounting substrate 10 at a temperature of about 200° C. under a pressure of 600N as a whole. For example, the light-emitting element 30 is a micro light-emitting diode (LED) having a side length of 50 μm or less in a plan view. For example, a surface 31PA facing the P-terminal 11P of the P-electrode 31P projects toward the P-terminal 11P, and a surface 31NA facing the N-terminal 11N of the N-electrode 31N projects toward the N-terminal 11N. The surfaces 31PA and 31NA may be projected curved surfaces. The P-electrode 31P is an example of a first electrode, and the N-electrode 31N is an example of a second electrode.

Subsequently, a test of the light-emitting elements 30 is performed (Step S8). An electroluminescence (EL) test and a photoluminescence (PL) test are described as examples of the test.

The EL test includes a step of performing a test of the light-emitting elements 30 by applying a voltage between the P-power supply pad 12P and the N-power supply pad 12N. In the EL test, each light-emitting element 30 that does not emit light even when a voltage is applied is regarded as a light-emitting element 30 that does not satisfy a certain criterion (hereinafter, also referred to as a defective light-emitting element).

The PL test includes a step of performing a test of the light-emitting elements 30 by irradiating the light-emitting elements 30 with excitation light. In the PL test, the P-terminal 11P and the N-terminal 11N are not electrically connected to each other, and each light-emitting element 30 that does not emit light even when being irradiated with the excitation light is regarded as a defective light-emitting element by assuming that a shorting (short circuit) has occurred inside the light-emitting element 30. It is noted that a metal film may be formed separately from the metal films 20P and 20N so as to electrically connect the P-terminal 11P and the N-terminal 11N, and in the PL test, each light-emitting element 30 that emits light when being irradiated with the excitation light may be regarded as a defective light-emitting element by assuming that an open circuit (disconnection) has occurred inside the light-emitting element 30.

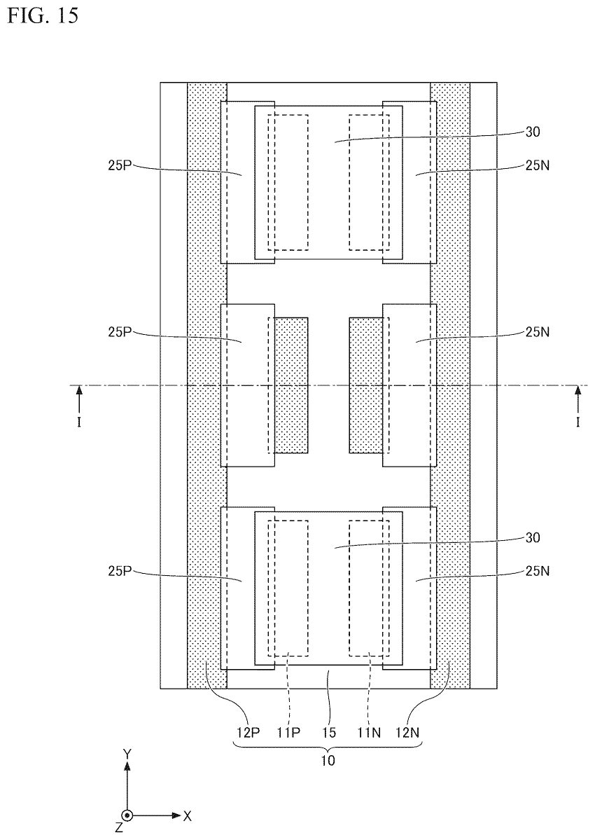

Subsequently, a determination of whether or not at least one defective light-emitting element is present as a result of the test in Step S8 is performed (Step S9). When at least one defective light-emitting element is present, as illustrated in FIG. 15, a step of removing the defective light-emitting element from the mounting substrate 10 is performed (Step S10). Then, the process returns to Step S7, and a step of mounting another light-emitting element 30 on the mounting substrate 10 by bringing the P-electrode 31P into contact with the upper surface 11PA of the P-terminal 11P and bringing the N-electrode 31N into contact with the upper surface 11NA of the N-terminal 11N in the portion in which the defective light-emitting element mounted has been removed is performed.

When the surface 31PA of the P-electrode 31P is curved and projecting toward the P-terminal 11P, the contact area between the surface 31PA and the upper surface 11PA is smaller than that in a case in which the surface 31PA is flat, and the P-electrode 31P can be easily separated from the P-terminal 11P. Similarly, when the surface 31NA of the N-electrode 31N is curved projecting toward the N-terminal 11N, the contact area between the surface 31NA and the upper surface 11NA is smaller than that in a case in which the surface 31NA is flat, and the N-electrode 31N can be easily separated from the N-terminal 11N. For that reason, when the surface 31PA of the P-electrode 31P is curved and projecting toward the P-terminal 11P and the surface 31NA of the N-electrode 31N is curved and projecting toward the N-terminal 11N, the defective light-emitting element can be easily removed from the mounting substrate 10 for replacement.

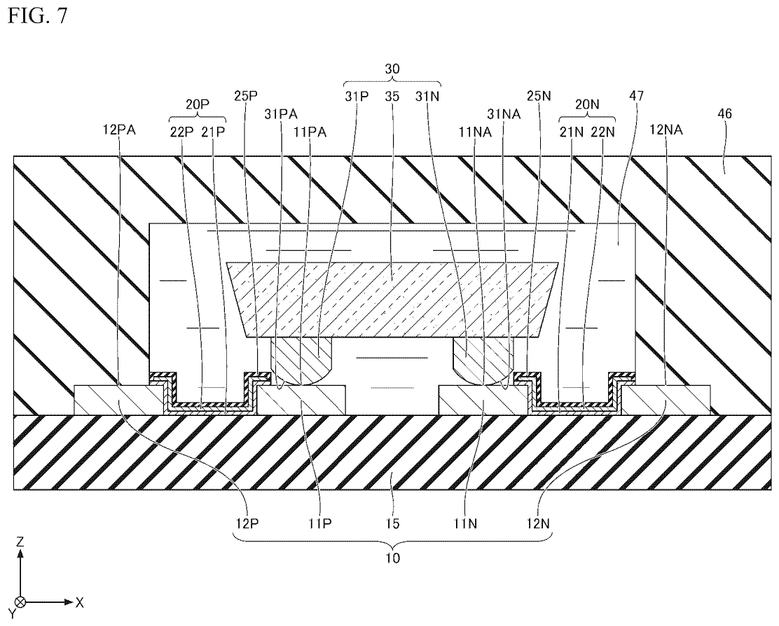

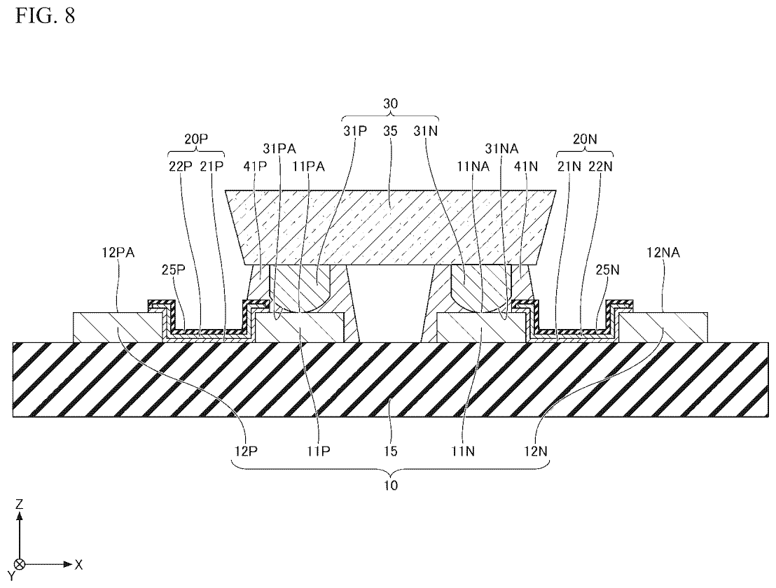

Then, the processes of Steps S7 to S10 are repeated until no defective light-emitting element is present. When it is determined that no defective light-emitting element is present in Step S9, as illustrated in FIGS. 7 and 8, a step of forming a plating film 41P and a plating film 41N is performed (Step S11). The material of the plating film 41P and the plating film 41N is, for example, gold. In the formation of the plating film 41P and the plating film 41N, for example, electrolytic gold plating processing accompanied by power supply from the P-power supply pad 12P and the N-power supply pad 12N is performed.

To be more specific, as illustrated in FIG. 7, the P-terminal 11P, the N-terminal 11N, the P-electrode 31P, and the N-electrode 31N are immersed in a plating solution 47 in a state in which the metal film 20P, the metal film 20N, the insulating film 25P, and the insulating film 25N remain formed. As the plating solution 47, a plating solution to which the metal film 20P and the metal film 20N have resistance is used. When the metal film 20P is formed with the titanium tungsten layer 21P and the aluminum layer 22P, and the metal film 20N is formed with the titanium tungsten layer 21N and the aluminum layer 22N, since aluminum is dissolved in an alkaline plating solution, the plating solution 47 is preferably acidic or neutral, and particularly preferably an acidic cyanide bath. In the plating process, a cover 46 may prevent the plating solution 47 from coming into contact with the P-power supply pad 12P and the N-power supply pad 12N.

As a result of such plating processing, as illustrated in FIG. 8, the plating film 41P is formed on the surfaces of the P-terminal 11P and the P-electrode 31P in a state in which the metal film 20P and the insulating film 25P remain formed, and the plating film 41N is formed on the surfaces of the N-terminal 11N and the N-electrode 31N in a state in which the metal film 20N and the insulating film 25N remain formed. Since there is a space between the light-emitting element 30 and the mounting substrate 10 in a state before immersion into the plating solution 47, the plating solution 47 can easily enter a portion between the light-emitting element 30 and the mounting substrate 10, and the plating film 41P and the plating film 41N can be easily formed. A part of the plating film 41P is formed on the metal film 20P disposed on a part of the upper surface 11PA of the P-terminal 11P, and a part of the plating film 41N is formed on the metal film 20N disposed on a part of the upper surface 11NA of the N-terminal 11N. In addition, due to the surface 31PA of the P-electrode 31P being curved and projecting toward the P-terminal 11P, a gap is present between the surface 31PA and the upper surface 11PA, but this gap is filled with the plating film 41P. As a result, an excellent bonding strength can be obtained between the P-electrode 31P and the P-terminal 11P. Similarly, due to the surface 31NA of the N-electrode 31N being curved and projecting toward the N-terminal 11N, a gap is present between the surface 31NA and the upper surface 11NA, but this gap is filled with the plating film 41N. As a result, an excellent bonding strength can be obtained between the N-electrode 31N and the N-terminal 11N. The plating film 41P is an example of a first plating film, and the plating film 41N is an example of a second plating film.

On the other hand, the insulating film 25P is formed on the front surface of the metal film 20P, and the insulating film 25N is formed on the front surface of the metal film 20N. For that reason, the plating film 41P does not grow from the metal film 20P, and the plating film 41N does not grow from the metal film 20N. In addition, since aluminum is a base metal, even if aluminum is mixed into the plating solution from the aluminum layer 22P or the aluminum layer 22N, electrodeposition of aluminum does not is less likely to occur.

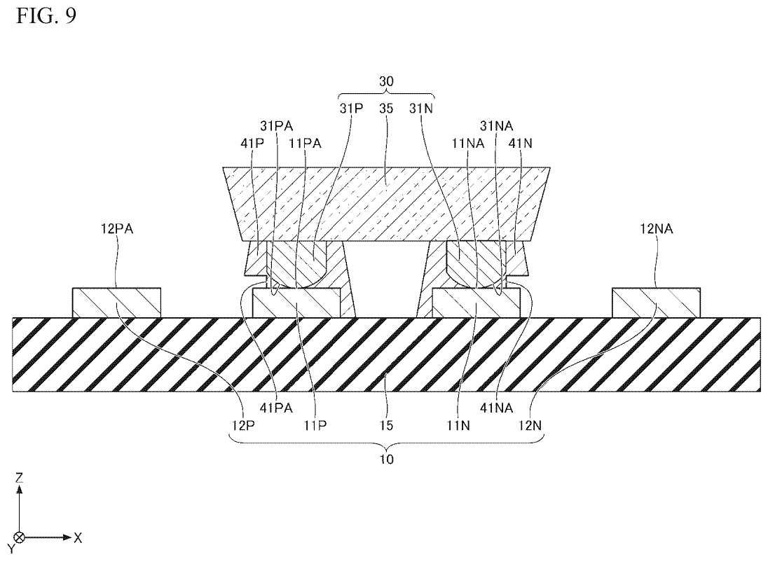

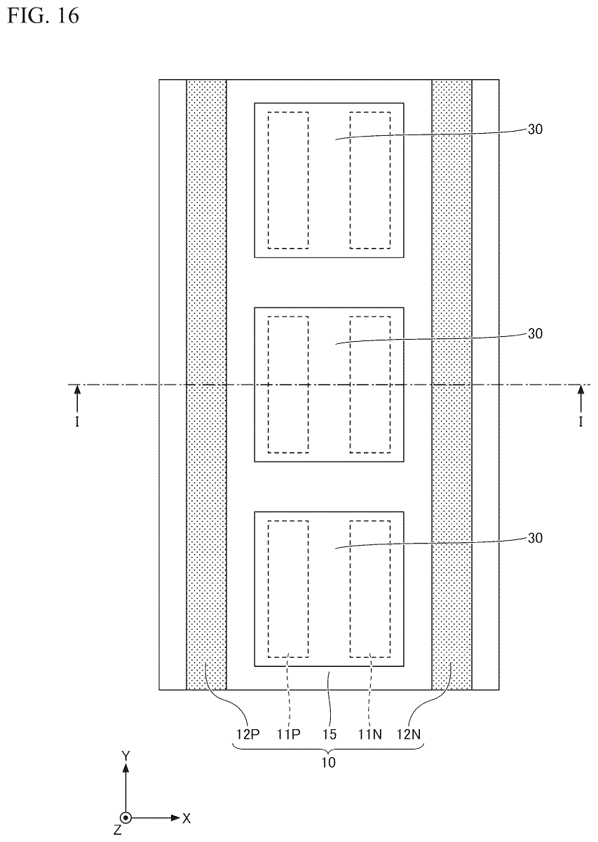

Subsequently, as illustrated in FIGS. 9 and 16, a step of removing the insulating film 25P, the metal film 20P, the insulating film 25N, and the metal film 20N is performed (Step S12). The insulating film 25P, the metal film 20P, the insulating film 25N, and the metal film 20N can be removed by, for example, wet etching. In the wet etching of the insulating film 25P, the aluminum layer 22P, the insulating film 25N, and the aluminum layer 22N, for example, an aqueous solution of tetramethylammonium hydroxide (TMAH), sodium hydroxide (NaOH), or phosphoric acetic and nitric acid is used as an etchant. When an aqueous solution of phosphoric acetic and nitric acid is used as the etchant, for example, an aqueous solution in which mixing percentages of phosphoric acid, nitric acid, acetic acid, and water are 80 mass %, 5 mass %, 5 mass %, and 10 mass %, respectively, may be used. In the wet etching of the titanium tungsten layer 21P and the titanium tungsten layer 21N, for example, an aqueous solution of hydrogen peroxide (H₂O₂) is used as an etchant. The P-terminal 11P, the N-terminal 11N, the P-electrode 31P, the N-electrode 31N, the plating film 41P, and the plating film 41N have higher resistance to an etchant used for the etching of the insulating film 25P, the metal film 20P, the insulating film 25N, and the metal film 20N than the metal film 20P and the metal film 20N. Therefore, when the insulating film 25P, the metal film 20P, the insulating film 25N, and the metal film 20N are etched, the P-terminal 11P, the N-terminal 11N, the P-electrode 31P, the N-electrode 31N, the plating film 41P, and the plating film 41N are not easily etched. Thus, it is possible to suppress formation of a sulfuration starting point in a light-emitting device 100, a decrease in a bonding strength between the light-emitting element 30 and the mounting substrate 10, and the like, which possibly occur due to the progress of etching.

As described above, a part of the plating film 41P is formed on the metal film 20P disposed on a part of the upper surface 11PA of the P-terminal 11P. Therefore, after the removal of the insulating film 25P and the metal film 20P, a recessed portion 41PA that includes the part of the upper surface 11PA of the P-terminal 11P and is recessed toward the P-electrode 31P is formed on a lateral surface of the plating film 41P. Similarly, a part of the plating film 41N is formed on the metal film 20N disposed on a part of the upper surface 11NA of the N-terminal 11N. Therefore, after the removal of the insulating film 25N and the metal film 20N, a recessed portion 41NA that includes the part of the upper surface 11NA of the N-terminal 11N and is recessed toward the N-electrode 31N is formed on a lateral surface of the plating film 41N. The recessed portion 41PA is an example of a first recessed portion, and the recessed portion 41NA is an example of a second recessed portion.

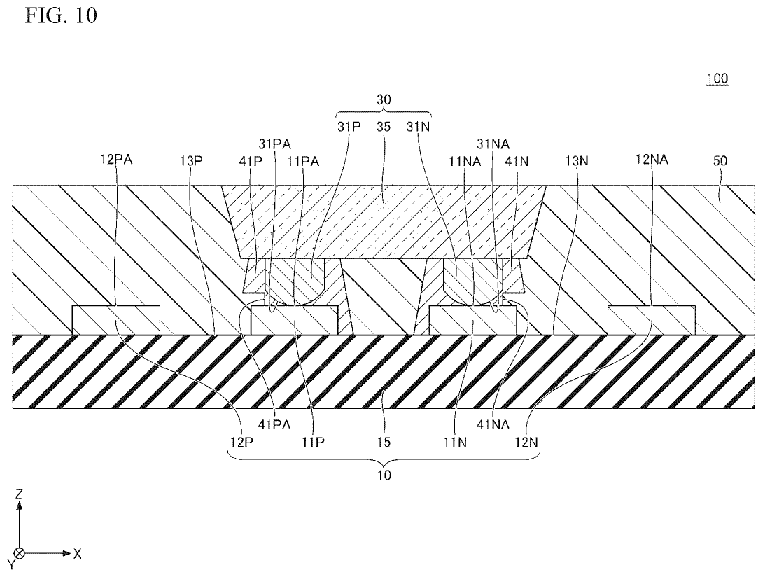

Subsequently, as illustrated in FIG. 10, a step of forming a light-reflective material 50 on the mounting substrate 10 so as to surround the light-emitting elements 30 in a plan view and be disposed in the recessed portion 41PA and the recessed portion 41NA is performed (Step S13). The light-reflective material 50 is formed using, for example, a white resin material containing titanium oxide powder.

As a result, the light-emitting device 100 can be manufactured.

In the manufacturing process of the light-emitting device 100, a defective light-emitting element is removed and replaced with another light-emitting element 30 that satisfies a certain criterion. Therefore, a high yield can be obtained. The removal of the defective light-emitting element is performed based on the result of the test of the light-emitting elements 30. In the present embodiment, since the metal film 20P and the metal film 20N are formed, the test of the light-emitting elements 30 can be performed before the formation of the plating film 41P and the plating film 41N. Therefore, the defective light-emitting element can be more easily removed.

In addition, the light-reflective material 50 not only surrounds the light-emitting elements 30 in a plan view, but the light-reflective material 50 is also disposed in the recessed portion 41PA and the recessed portion 41NA. For that reason, adhesion between the light-reflective material 50 and each of the mounting substrate 10 and the light-emitting element 30 is improved by an anchor effect, and detachment of the light-reflective material 50 from the light-emitting device 100 can be suppressed.

Further, since the metal film 20P is formed covering a part of the upper surface 11PA of the P-terminal 11P and a part of the upper surface 12PA of the P-power supply pad 12P, even when a slight positional deviation occurs in the position of the mask 51, the electrical connection between the metal film 20P and each of the P-terminal 11P and the P-power supply pad 12P can be ensured. Similarly, since the metal film 20N is formed covering a part of the upper surface 11NA of the N-terminal 11N and a part of the upper surface 12NA of the N-power supply pad 12N, even when a slight positional deviation occurs in the position of the mask 51, the electrical connection between the metal film 20N and each of the N-terminal 11N and the N-power supply pad 12N can be ensured.

The presence or absence of a defective light-emitting element is determined in Step S9, and the process may proceed to Step S10 when the proportion of defective light-emitting elements is equal to or higher than a predetermined value, or proceed to Step S11 when the proportion thereof is less than the predetermined value. That is, for example, when a lighting rate equal to or higher than a reference value is obtained in the light-emitting device 100, even when the lighting rate is not 100%, the process need not proceed to Step S10, and the plating films 41P and 41N may be formed in Step S11.

### Second Embodiment

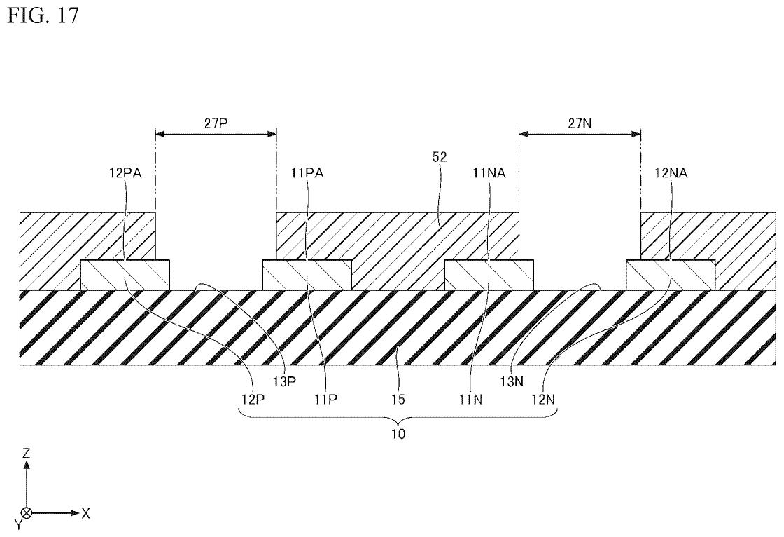

Subsequently, a second embodiment will be described. The second embodiment is different from the first embodiment mainly in a forming method of the metal film 20P and the metal film 20N. FIGS. 17 to 19 are cross-sectional diagrams to illustrate process steps of a manufacturing method for a light-emitting device according to the second embodiment.

In the second embodiment, first, as in the first embodiment, a step of preparing the mounting substrate 10 is performed. Subsequently, as illustrated in FIG. 17, a step of forming a mask 52 on the front surface side of the mounting substrate 10 excluding the first region 27P and the second region 27N is performed. The mask 52 is formed by, for example, applying, exposing, and developing a resist.

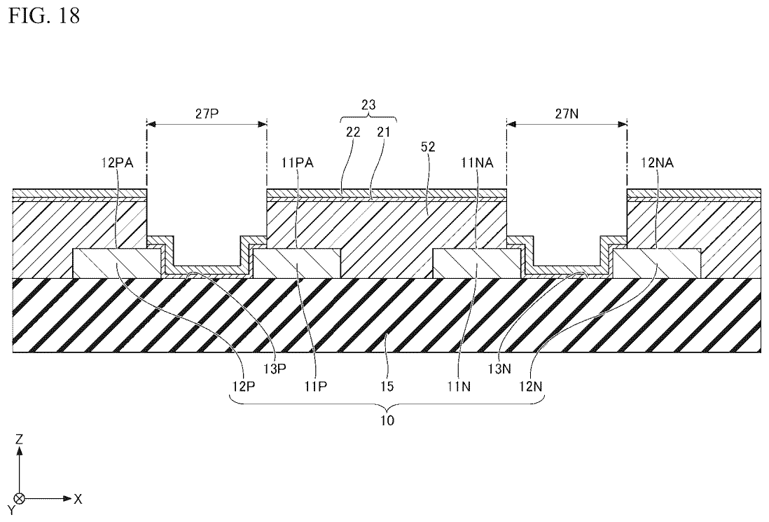

Subsequently, as illustrated in FIG. 18, a step of forming the metal film 23 that covers a surface of the mask 52 and portions of the front surface of the mounting substrate 10 that are not covered with the mask 52 is performed. The metal film 23 can be formed by a method similar to the method of the first embodiment. The metal film 23 is formed on an upper surface of the mask 52, but is not formed on lateral surfaces of the mask 52.

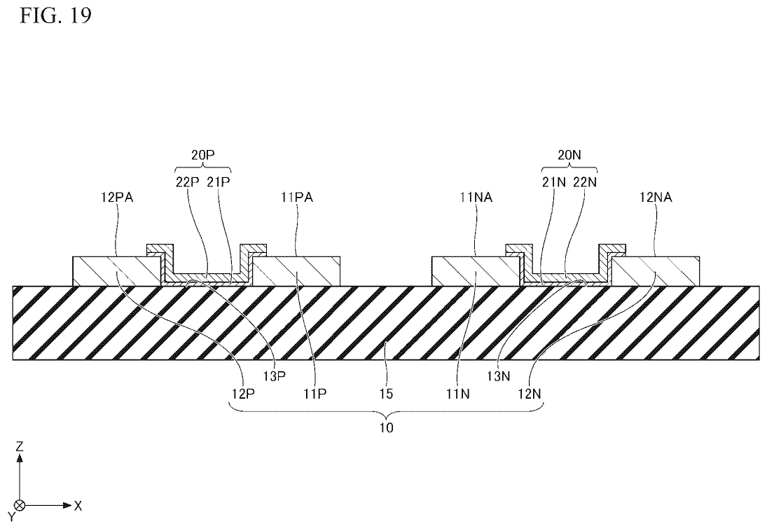

Subsequently, as illustrated in FIG. 19, a step of removing the mask 52 and the metal film 23 formed on the mask 52 is performed. In other words, a lift-off is performed. As a result of this step, in the first region 27P of the metal film 23, the metal film 20P that electrically connects the P-terminal 11P and the P-power supply pad 12P is formed covering a part of the upper surface 11PA of the P-terminal 11P and a part of the upper surface 12PA of the P-power supply pad 12P. In addition, in the second region 27N of the metal film 23, the metal film 20N that electrically connects the N-terminal 11N and the N-power supply pad 12N is formed covering a part of the upper surface 11NA of the N-terminal 11N and a part of the upper surface 12NA of the N-power supply pad 12N.

Then, as in the first embodiment, a step of forming the insulating film 25P and the insulating film 25N and the subsequent steps are performed.

As a result, the light-emitting device 100 can be manufactured.

Also in the second embodiment, as in the first embodiment, a defective light-emitting element is removed in the manufacturing process of the light-emitting device 100 and is replaced with another light-emitting element 30 that satisfies a certain criterion, and therefore a high yield can be obtained. In addition, the detachment of the light-reflective material 50 from the light-emitting device 100 can be suppressed.

Moreover, even when a slight positional deviation occurs in the position of the mask 52, the electrical connection between the metal film 20P and each of the P-terminal 11P and the P-power supply pad 12P can be ensured, and the electrical connection between the metal film 20N and each of the N-terminal 11N and the N-power supply pad 12N can be ensured.

### Modified Example of Second Embodiment

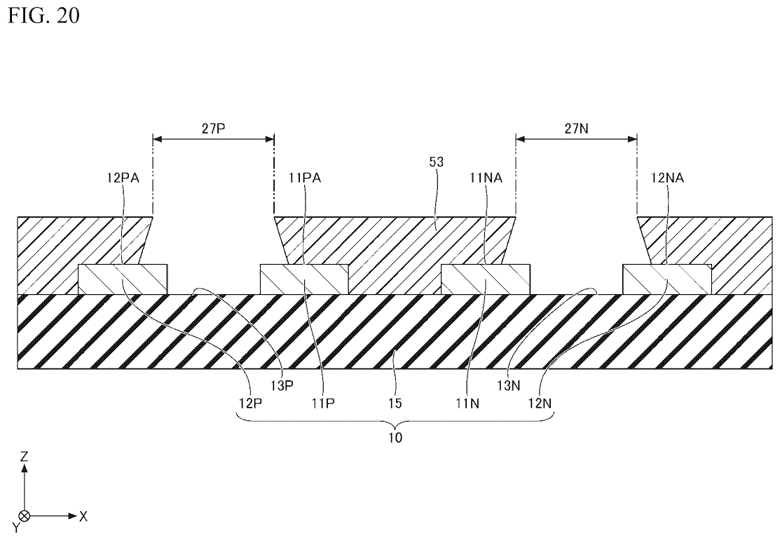

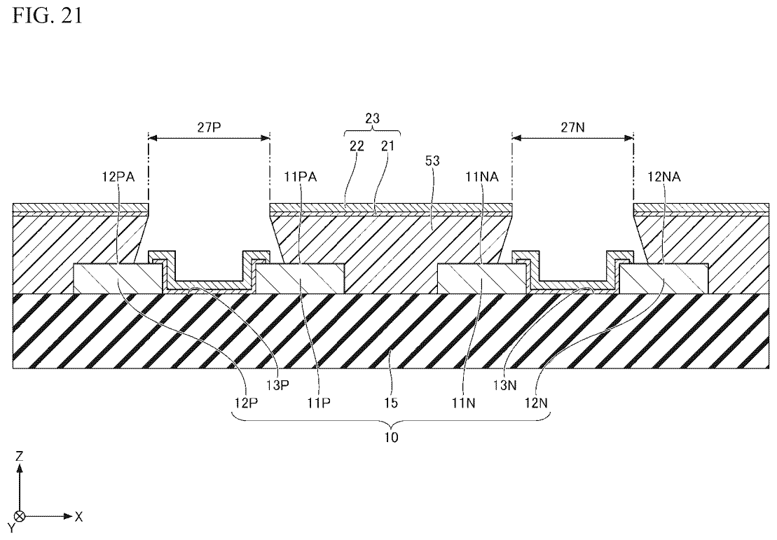

Subsequently, a modified example of the second embodiment will be described. The modified example of the second embodiment differs from the second embodiment mainly in the shape of the mask. FIGS. 20 to 21 are cross-sectional diagrams to illustrate process steps of a manufacturing method for a light-emitting device according to the modified example of the second embodiment.

In the modified example of the second embodiment, first, as in the first embodiment, a step of preparing the mounting substrate 10 is performed. Subsequently, as illustrated in FIG. 20, a step of forming a mask 53 on the front surface side of the mounting substrate 10 excluding the first region 27P and the second region 27N in a top view is performed. An opening portion of the mask 53 has a reverse-tapered shape that widens toward the mounting substrate 10. The mask 53 is formed by, for example, applying, exposing, and developing a resist.

Subsequently, as illustrated in FIG. 21, a step of forming the metal film 23 that covers a surface of the mask 53 and portions of the front surface of the mounting substrate 10 that are not covered with the mask 53 is performed. The metal film 23 can be formed by a method similar to the method of the first embodiment. The metal film 23 is formed on an upper surface of the mask 53, but is not formed on a lateral surface of the mask 53. In addition, since the opening portion of the mask 53 has a reverse-tapered shape, the aluminum layer 22 covers not only an upper surface of the titanium tungsten layer 21 but also lateral surfaces thereof on the upper surface 11PA of the P-terminal 11P, the upper surface 11NA of the N-terminal 11N, the upper surface 12PA of the P-power supply pad 12P, and the upper surface 12NA of the N-power supply pad 12N.

Subsequently, as in the second embodiment, a step of removing the mask 53 and the metal film 23 formed on the mask 53 is performed.

Then, as in the first embodiment, a step of forming the insulating film 25P and the insulating film 25N and the subsequent steps are performed.

As a result, the light-emitting device 100 can be manufactured.

In the modified example of the second embodiment, the aluminum layer 22 is formed covering not only the upper surface of the titanium tungsten layer 21 but also the lateral surfaces thereof. Therefore, lateral surfaces of the titanium tungsten layer 21P are covered with the insulating film 25P, and lateral surfaces of the titanium tungsten layer 21N are covered with the insulating film 25N. Therefore, the titanium tungsten layer 21P and the titanium tungsten layer 21N do not come into contact with the plating solution 47, and the growth of the plating film 41P from the titanium tungsten layer 21P and the growth of the plating film 41N from the titanium tungsten layer 21N can be suppressed.

### Arrangement Example of Metal Film

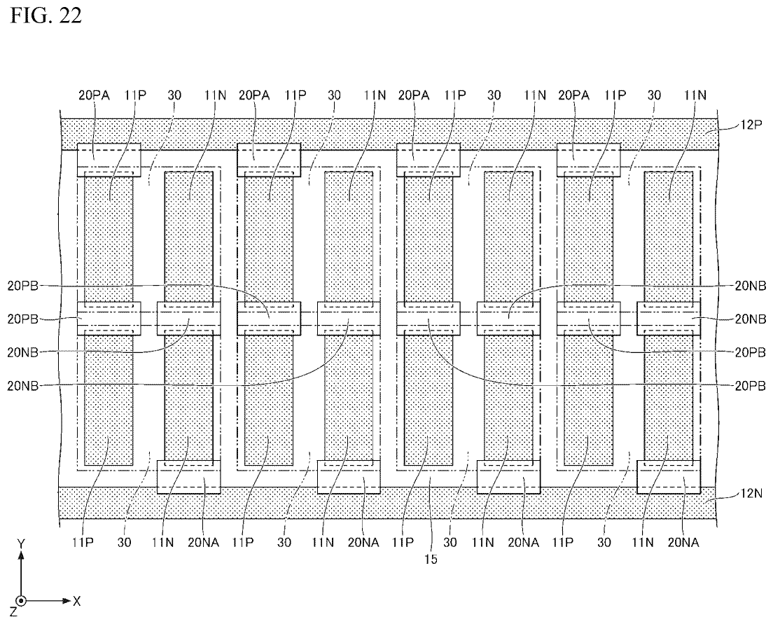

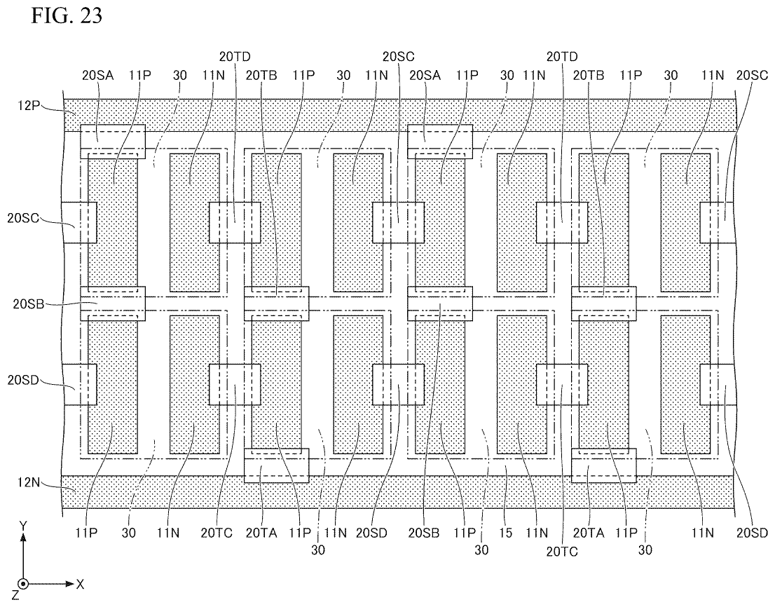

Subsequently, an example of an arrangement of the metal films connected to the P-terminal 11P and the metal films connected to the N-terminal 11N will be described. FIG. 22 is a top-view diagram illustrating a first example of the arrangement of the metal films. FIG. 23 is a top-view diagram illustrating a second example of the arrangement of the metal films.

In the first example, as illustrated in FIG. 22, the P-terminals 11P and the N-terminals 11N are alternately disposed along the X-axis. Although two rows of the P-terminals 11P and the N-terminals 11N are provided, three or more rows thereof may be provided. In the example illustrated in FIG. 22, two rows of the P-terminals 11P and the N-terminals 11N are arranged along the Y-axis. Two P-terminals 11P are arranged along the Y-axis, and two N-terminals 11N are arranged along the Y-axis. The P-power supply pad 12P and the N-power supply pad 12N extending along the X-axis are disposed with the two rows of the P-terminals 11P and the N-terminals 11N interposed therebetween. For example, the P-power supply pad 12P is located on the +Y side of the N-power supply pad 12N. The light-emitting element 30 is mounted on the P-terminal 11P and the N-terminal 11N adjacent to each other along the X-axis by bringing the P-electrode 31P into contact with the P-terminal 11P and bringing the N-electrode 31N into contact with the N-terminal 11N. In addition, in the first example, metal films 20PA and 20PB are provided instead of the metal film 20P, and metal films 20NA and 20NB are provided instead of the metal film 20N.

The metal film 20PA is provided in contact with the P-terminal 11P located on the +Y side and the P-power supply pad 12P. The metal film 20PB is provided in contact with the P-terminal 11P located on the +Y side and the P-terminal 11P located on the −Y side. When three or more rows of the P-terminals 11P and the N-terminals 11N are provided, the metal film 20PA is provided in contact with the P-terminal 11P located on the most+Y side and the P-power supply pad 12P. The metal film 20PB is provided in contact with two P-terminals 11P adjacent to each other along the Y-axis.

The metal film 20NA is provided in contact with the N-terminal 11N located on the −Y side and the N-power supply pad 12N. The metal film 20NB is provided in contact with the N-terminal 11N located on the +Y side and the N-terminal 11N located on the −Y side. When three or more rows of the P-terminals 11P and the N-terminals 11N are provided, the metal film 20NB is provided in contact with the N-terminal 11N located on the most −Y side and the N-power supply pad 12N. The metal film 20NB is provided in contact with two N-terminals 11N adjacent to each other along the Y-axis.

In the EL test, when a forward voltage is applied between the P-power supply pad 12P and the N-power supply pad 12N, that is, when a voltage at which the potential of the P-power supply pad 12P is higher than the potential of the N-power supply pad 12N is applied, the forward voltage is supplied to all of the light-emitting elements 30. Therefore, when all of the light-emitting elements 30 are normal, all of the light-emitting elements 30 emit light.

Therefore, in the first example, the light emission states of all of the light-emitting elements 30 can be checked by applying a voltage once.

In the second example, as illustrated in FIG. 23, the P-terminals 11P, the N-terminals 11N, the P-power supply pad 12P, and the N-power supply pad 12N are disposed as in the first example. As in the first example, three or more rows of the P-terminals 11P and the N-terminals 11N may be provided. The light-emitting element 30 is mounted on the P-terminal 11P and the N-terminal 11N adjacent to each other along the X-axis by bringing the P-electrode 31P into contact with the P-terminal 11P and bringing the N-electrode 31N into contact with the N-terminal 11N. In the second example, metal films 20SA, 20SB, 20SC, and 20SD are provided instead of the metal film 20P, and metal films 20TA, 20TB, 20TC, and 20TD are provided instead of the metal film 20N.

The metal film 20SA is provided in contact with the P-terminal 11P located on the +Y side and the P-power supply pad 12P. However, the metal film 20SA is provided in contact with not all of the P-terminals 11P located on the +Y side, but every other P-terminal 11P located on the +Y side along the X-axis. The metal film 20SB is provided in contact with the P-terminal 11P on which the metal film 20SA is provided and the P-terminal 11P located on the −Y side of the P-terminal 11P. The metal film 20SC is provided in contact with the P-terminal 11P on which the metal film 20SA is provided and the N-terminal 11N located on the −X side of the P-terminal 11P. The metal film 20SD is provided in contact with the P-terminal 11P on which the metal film 20SB is provided and the metal film 20SA is not provided, and the N-terminal 11N located on the −X side of the P-terminal 11P.

When three or more rows of the P-terminals 11P and the N-terminals 11N are provided, the metal film 20SA is provided in contact with every other P-terminal 11P located on the most+Y side along the X-axis and the P-power supply pad 12P. The metal film 20SB is provided in contact with two P-terminals 11P adjacent to each other along the Y-axis. The metal film 20SC is provided in contact with the P-terminal 11P on which the metal film 20SA is provided and the N-terminal 11N located on the −X side of the P-terminal 11P. The metal film 20SD is provided in contact with the P-terminal 11P on which the metal film 20SB is provided on the +Y side and the N-terminal 11N located on the −X side of the P-terminal 11P.

The metal film 20TA is provided in contact with the P-terminal 11P located on the −Y side and the N-power supply pad 12N. However, the metal film 20TA is provided in contact with not all of the P-terminals 11P located on the −Y side, but every other P-terminal 11P located on the −Y side along the X-axis. More specifically, the metal film 20TA is provided in contact with the P-terminal 11P located on the −Y side with which the metal film 20SB is not in contact. The metal film 20TB is provided in contact with the P-terminal 11P on which the metal film 20TA is provided and the P-terminal 11P located on the +Y side of the P-terminal 11P. The metal film 20TC is provided in contact with the P-terminal 11P on which the metal film 20TA is provided and the N-terminal 11N located on the −X side of the P-terminal 11P. The metal film 20TD is provided in contact with the P-terminal 11P on which the metal film 20TB is provided and the metal film 20TA is not provided, and the N-terminal 11N located on the −X side of the P-terminal 11P.

When three or more rows of the P-terminals 11P and the N-terminals 11N are provided, the metal film 20TA is provided in contact with every other P-terminal 11P located on the most −Y side along the X-axis with which the metal film 20SB is not in contact, and the N-power supply pad 12N. The metal film 20TB is provided in contact with two P-terminals 11P adjacent to each other along the Y-axis. The metal film 20TC is provided in contact with the P-terminal 11P on which the metal film 20TA is provided and the N-terminal 11N located on the −X side of the P-terminal 11P. The metal film 20TD is provided in contact with the P-terminal 11P on which the metal film 20TB is provided on the −Y side and the N-terminal 11N located on the −X side of the P-terminal 11P.

In the EL test, when a forward voltage is applied between the P-power supply pad 12P and the N-power supply pad 12N, the forward voltage is supplied to a group of light-emitting elements 30 in which the P-electrode 31P is connected to the P-power supply pad 12P through the metal film 20SA and the N-electrode 31N is connected to the N-power supply pad 12N through the metal film 20TA. On the other hand, a reverse voltage is supplied to another group of light-emitting elements 30 in which the P-electrode 31P is connected to the N-power supply pad 12N through the metal film 20TA and the N-electrode 31N is connected to the P-power supply pad 12P through the metal film 20SA. Therefore, even when all of the light-emitting elements 30 are normal, half of the light-emitting elements 30 emit light.

In the EL test, when a reverse voltage is applied between the P-power supply pad 12P and the N-power supply pad 12N, that is, when a voltage at which the potential of the N-power supply pad 12N is higher than the potential of the P-power supply pad 12P is applied, a forward voltage is supplied to a group of light-emitting elements 30 in which the P-electrode 31P is connected to the N-power supply pad 12N through the metal film 20TA and the N-electrode 31N is connected to the P-power supply pad 12P through the metal film 20SA. On the other hand, a reverse voltage is supplied to another group of light-emitting elements 30 in which the P-electrode 31P is connected to the P-power supply pad 12P through the metal film 20SA and the N-electrode 31N is connected to the N-power supply pad 12N through the metal film 20TA. Therefore, also in this case, even when all of the light-emitting elements 30 are normal, half of the light-emitting elements 30 emit light.

Therefore, in the second example, the overall light emission intensity is low compared with the first example, and the light-emitting element 30 that does not emit light can be easily detected.

1. A manufacturing method for a light-emitting device, comprising:
on a mounting substrate having a first terminal, a second terminal, a first pad, and a second pad, forming a first metal film electrically connecting the first terminal and the first pad on the mounting substrate such that the first metal film covers a part of an upper surface of the first terminal and a part of an upper surface of the first pad, and a second metal film electrically connecting the second terminal and the second pad on the mounting substrate such that the second metal film covers a part of an upper surface of the second terminal and a part of an upper surface of the second pad;
forming a first insulating film by insulating a front surface side of the first metal film while maintaining electrical connection between the first terminal and the first pad, and a second insulating film by insulating a front surface side of the second metal film while maintaining electrical connection between the second terminal and the second pad;
mounting a light-emitting element having a first electrode and a second electrode on the mounting substrate by bringing the first electrode into contact with the upper surface of the first terminal and bringing the second electrode into contact with the upper surface of the second terminal;
forming a first plating film on surfaces of the first terminal and the first electrode in a state in which the first metal film and the first insulating film remain formed, and a second plating film on surfaces of the second terminal and the second electrode in a state in which the second metal film and the second insulating film remain formed; and
removing the first insulating film, the first metal film, the second insulating film, and the second metal film after the first plating film and the second plating film are formed.

2. The manufacturing method according to claim 1, wherein
said forming the first metal film and the second metal film comprises:
forming a third metal film that covers at least the first terminal, the second terminal, the first pad, the second pad, a first portion of a front surface of the mounting substrate, and a second portion of the front surface of the mounting substrate, the first portion being exposed between the first terminal and the first pad, the second portion being exposed between the second terminal and the second pad;
forming a mask on a first region and a second region of the third metal film;
removing a portion of the third metal film that is not covered with the mask, wherein the first region of the third metal film that remains after said removing serves as the first metal film and the second region of the third metal film that remains after said removing serves as the second metal film; and
removing the mask.

3. The manufacturing method according to claim 1, wherein
said forming the first metal film and the second metal film comprises:
forming a mask on a side of a front surface of the mounting substrate having a first opening at a first region and a second opening at a second region;
forming a third metal film that covers a surface of the mask and a portion of the front surface of the mounting substrate at the first and second regions; and
removing the mask and a first part of the third metal film formed on the mask, wherein a second part of the third metal film remaining in the first region serves as the first metal film and a third part of the third metal film remaining in the second region serves as the second metal film.

4. The manufacturing method according to claim 3, wherein
the mask has reverse-tapered side surfaces in the first and second openings, and
the third metal film includes a first metal layer and a second metal layer above the first metal layer, the second metal layer covering side surfaces of the first metal layer at the first and second regions.

5. The manufacturing method according to claim 1, wherein
each of the first metal film and the second metal film comprises a plurality of layers, and one of the layers located closest to a front surface of each of the first metal film and the second metal film contains aluminum, chromium, or an alloy of tungsten and titanium.

6. The manufacturing method according to claim 1, wherein
said removing the first insulating film, the first metal film, the second insulating film, and the second metal film is performed by etching, and
the first terminal, the second terminal, the first electrode, the second electrode, the first plating film, and the second plating film have higher resistance to an etchant used for the etching than the first metal film and the second metal film.

7. The manufacturing method according to claim 1, wherein
in said forming the first plating film and the second plating film, the first plating film is formed on a region of the first metal film disposed on the part of the upper surface of the first terminal, and the second plating film is formed on a region of the second metal film disposed on the part of the upper surface of the second terminal,
in said removing the first insulating film, the first metal film, the second insulating film, and the second metal film, a first recessed portion comprising the part of the upper surface of the first terminal and being recessed toward the first electrode is formed on a lateral surface of the first plating film, and a second recessed portion comprising the part of the upper surface of the second terminal and being recessed toward the second electrode is formed on a lateral surface of the second plating film, and
the method further comprises after said removing the first insulating film, the first metal film, the second insulating film, and the second metal film, forming a light-reflective material on the mounting substrate such that the light-reflective material surrounds the light-emitting element in a plan view and is disposed in the first recessed portion and the second recessed portion.

8. The manufacturing method according to claim 1, wherein
a surface of the first electrode facing the first terminal projects toward the first terminal, and
a surface of the second electrode facing the second terminal projects toward the second terminal.

9. The manufacturing method according to claim 8, wherein
the surface of the first electrode facing the first terminal includes a first curved portion projecting toward the first terminal, and the surface of the second electrode facing the second terminal includes a second curved portion projecting toward the second terminal, and
the first plating film is formed at a space between the first curved portion and the first terminal, and the second plating film is formed at a space between the second curved portion and the second terminal.

10. The manufacturing method according to claim 1, wherein
after said mounting the light-emitting element on the mounting substrate and before said forming the first plating film and the second plating film, the manufacturing method further comprises:
performing a test of the light-emitting element by applying a voltage between the first pad and the second pad;
removing the light-emitting element from the mounting substrate when the light-emitting element is determined to be defective according to the test; and
mounting another light-emitting element having a first electrode and a second electrode on the mounting substrate by bringing the first electrode of the another light-emitting element into contact with the upper surface of the first terminal and bringing the second electrode of the another light-emitting element into contact with the upper surface of the second terminal.

11. The manufacturing method according to claim 1, wherein
after said mounting the light-emitting element on the mounting substrate and before said forming the first plating film and the second plating film, the manufacturing method further comprises:
performing a test of the light-emitting element by irradiating the light-emitting element with excitation light;
removing the light-emitting element from the mounting substrate when the light-emitting element is determined to be defective according to the test; and
mounting another light-emitting element having a first electrode and a second electrode on the mounting substrate by bringing the first electrode of the another light-emitting element into contact with the upper surface of the first terminal and bringing the second electrode of the another light-emitting element into contact with the upper surface of the second terminal.

12. A light-emitting device comprising:
a mounting substrate having a first terminal, a second terminal, a first pad, and a second pad;
a light-emitting element having a first electrode and a second electrode, the first electrode being in contact with an upper surface of the first terminal, the second electrode being in contact with an upper surface of the second terminal;
a first plating film formed on surfaces of the first terminal and the first electrode;
a second plating film formed on surfaces of the second terminal and the second electrode; and
a light-reflective material formed on the mounting substrate and surrounding the light-emitting element in a plan view, wherein
a first recessed portion comprising a part of the upper surface of the first terminal and being recessed toward the first electrode is formed on a lateral surface of the first plating film,
a second recessed portion comprising a part of the upper surface of the second terminal and being recessed toward the second electrode is formed on a lateral surface of the second plating film, and
the light-reflective material is disposed in the first recessed portion and the second recessed portion.

13. The light-emitting device according to claim 12, wherein
a surface of the first electrode facing the first terminal projects toward the first terminal, and
a surface of the second electrode facing the second terminal projects toward the second terminal.

14. The light-emitting device according to claim 13, wherein
the surface of the first electrode facing the first terminal includes a first curved portion projecting toward the first terminal, and the surface of the second electrode facing the second terminal includes a second curved portion projecting toward the second terminal, and
the first plating film is formed at a space between the first curved portion and the first terminal, and the second plating film is formed at a space between the second curved portion and the second terminal.

15. A manufacturing method for a light-emitting device, comprising:
on a mounting substrate having a first pad, a plurality of first terminals, a second pad, and a plurality of second terminals, forming a first metal film electrically connecting the first pad to at least a part of the plurality of first terminals and a second metal film electrically connecting the second pad to at least a part of the plurality of second terminals;
mounting a plurality of light-emitting elements on the mounting substrate with the first and second metal films, each of the light-emitting elements having a first electrode mounted on one of the first terminals and a second electrode mounted on one of the second terminals;
performing a test of the plurality of light-emitting elements;
replacing at least one of the plurality of light-emitting elements that is determined to be defective according to the test; and
after said replacing, bonding the first electrode of each of the plurality of light-emitting elements with one of the plurality of first terminals with a first plating film and bonding the second electrode of each of the plurality of light-emitting elements with one of the plurality of second terminals with a second plating film.

16. The manufacturing method according to claim 15, further comprising:
after said bonding, removing the first and second metal films.

17. The manufacturing method according to claim 15, wherein
the first pad and the second pad extend in parallel in a first direction,
the plurality of first terminals is aligned in the first direction between the first pad and the second pad, and
the plurality of second terminals is aligned in the first direction between the plurality of first terminals and the second pad, at positions adjacent to the plurality of first terminals, respectively.

18. The manufacturing method according to claim 15, wherein
the first pad and the second pad extend in parallel in a first direction, and
the mounting substrate includes a plurality of regions between the first pad and second pad, the plurality of regions being arranged in a matrix with a plurality of rows in the first direction and a plurality of columns in a second direction crossing the first direction, one of the plurality of first terminals and one of the plurality of second terminals being disposed adjacent to each other in each of the plurality of regions.

19. The manufacturing method according to claim 18, wherein
the first metal film electrically connects each of the plurality of first terminals to the first pad,
the second metal film electrically connects each of the plurality of second terminals to the second pad, and
the test comprises concurrently turning on each of the plurality of light-emitting elements by applying a voltage between the first pad and the second pad.

20. The manufacturing method according to claim 18, wherein
the first metal film electrically connects each of first terminals in a first group to the first pad and each of second terminals in a first group to one of the first terminals in the first group,
the second metal film electrically connects each of second terminals in a second group to the second pad via one of first terminals in a second group, and
the test comprises selectively turning on a first part of the plurality of light-emitting elements connected to the first and second terminals in the first group, but not in the second group, and selectively turning on a second part of the plurality of light-emitting elements connected to the first and second terminals in the second group, but not in the first group.
